(19) United States
(12) Patent Application Publication
(10) Pub. No.: US 2010/0031989 A1
(43) Pub. Date: Feb. 11, 2010

(54) THERMOELECTRIC MODULE AND METALLIZED SUBSTRATE

(75) Inventors: Akio Kinoshi, Kanagawa (JP); Masataka Yamanashi, Kanagawa (JP); Hirofumi Hajime, Kanagawa (JP); Shingo Fujikawa, Kanagawa (JP)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(73) Assignee: KELK LTD., Hiratsuka-shi (JP)

(21) Appl. No.: 12/447,762

(22) PCT Filed: Oct. 22, 2007
(86) PCT No.: PCT/JP2007/070560

§ 371 Date: Apr. 29, 2009

(30) Foreign Application Priority Data
Oct. 30, 2006 (JP) 2006-293960

(51) Int. Cl. H01L 35/28

(52) U.S. Cl. 136/203

(57) ABSTRACT

A thermoelectric module (1) utilizing the Peltier effect, exhibiting an element-occupied area ratio of 40% or below, the element-occupied area ratio defined as the ratio of the sum of cross-sectional areas, perpendicular to the direction of electric current passage, of thermoelectric elements (5a,5b) to the area of insulating substrate (2a) being in contact with an object to be cooled via a metalized layer (4a), wherein metalized layers (4a,4b) are provided with slits. In this construction, there can be prevented breakage of thermoelectric device by thermal stress occurring at assembly, or thermal stress occurring at pre-tinning conducted in advance for attaching an object to be cooled or at attaching package, etc.

### TECHNICAL FIELD

The present invention relates to a thermoelectric module substrate utilizing the Peltier effect for use in thermoelectric conversion such as heat absorption or cooling, and also relates to a thermoelectric module using the substrate.

### BACKGROUND ART

Thermoelectric modules utilizing the Peltier effect are simple in configuration and easy to reduce the size and weight thereof. Furthermore, they are operable without noise and vibration, and their accuracy and response are very high. Therefore, these thermoelectric modules are applied in various fields, including temperature controllers in semiconductor devices such as semiconductor lasers, and semiconductor manufacturing equipment. A thermoelectric module has a plurality of thermoelectric elements arrayed on a substrate. FIG. 1 is a side view showing a thermoelectric module used, for example, for temperature control of a semiconductor laser. This thermoelectric module 1 has two insulating substrates 2a and 2b arranged in parallel with a space from each other. A plurality of metal electrodes 3a are formed on the surface of the insulating substrate 2a facing the insulating substrate 2b, while a metalized layer 4a is formed on the other surface not facing the insulating substrate 2b. Metal electrodes 3b are formed on the surface of the insulating substrate 2b facing the insulating substrate 2a, while a metalized layer 4b is formed on the other surface not facing the insulating substrate 2a. Current terminals 6 for receiving power supplied externally through lead wire or the like are provided on the surface of the insulating substrate 2b facing the insulating substrate 2a. Herein, an integral component formed by the insulating substrate 2a, the metal electrodes 3a, and the metalized layer 4a is referred to as the lower metalized substrate 10a, and an integral component formed by the insulating substrate 2b, the metal electrodes 3b, the metalized layer 4b, and the current terminals 6 is referred to as the upper metalized substrate 10b. A plurality of P-type thermoelectric elements 5a and a plurality of N-type thermoelectric elements 5b are provided between the insulating substrate 2a and the insulating substrate 2b, and these P-type and N-type thermoelectric elements 5a and 5b are alternately connected in series by means of the metal electrodes 3a and 3b. Thus, heat flow is generated between the insulating substrate 2a and the insulating substrate 2b by supplying electric current through a current pathway formed by the current terminals 6, the metal electrodes 3a, the metal electrodes 3b, the P-type thermoelectric elements 5a, and the N-type thermoelectric elements 5b.

Recent trend of downsizing and reduction of power consumption of communication semiconductor lasers requires downsizing and reduction of power consumption of thermoelectric modules as well. On the other hand, the use of lead-free solder is increased due to environmental concerns, and the temperature for soldering to bond thermoelectric modules to semiconductor lasers or to bond thermoelectric modules to packages tends to be increased. As a result, even higher temperature solder has become to be used as a solder material for assembling thermoelectric modules.

### DISCLOSURE OF THE INVENTION

### Problems To Be Solved by the Invention

However, since the cross-sectional area of the thermoelectric elements becomes smaller in a downsized and power-saving thermoelectric module as described above, the mechanical strength of the thermoelectric elements decreases. Moreover, the cooling-side surface area of the upper metalized substrate of the thermoelectric module for mounting a semiconductor laser cannot be made smaller in view of assembling workability and so on. As a result, the ratio of the area occupied by the thermoelectric elements relative to the area of the metalized substrate of the thermoelectric module becomes smaller, and thus the mechanical strength of the module as a whole decreases. This induces a problem of breakage of the thermoelectric elements caused by thermal stress generated during assembly, or during pre-tinning performed for attaching a package or an object to be cooled.

### Means for Solving the Problems

In the course of keen studies for meeting the needs for downsized and power-saving thermoelectric modules, the inventors found that the ratio of the thermoelectric element area to the area of the insulating substrate (the element occupying area ratio) was as low as 40% or less in some cases. In such cases, the thermoelectric elements are susceptible to breakage due to thermal stress generated during assembly or pre-tinning, which deteriorates the production yield. The present invention provides a metalized substrate for thermoelectric modules and a downsized and power-saving thermoelectric module utilizing such a metalized substrate, in which the risk of breakage of elements caused by thermal stress generated during assembly or pre-tinning is eliminated even if the element occupying area ratio is 40% or less.

In a thermoelectric module utilizing the Peltier effect, the stress is reduced even if the thermoelectric module has an element occupying area ratio of 40% or less, by forming a slit in an effective metalized region of a metalized substrate.

The stress is reduced for a thermoelectric module having an element occupying area ratio of 40% or less, by using a metalized substrate characterized in that the proportion of the area of an effective metalized region defined by the outer periphery of a metalized layer relative to the area of an effective element array region defined by the outer periphery of a metal electrode is 130% or less.

The stress is reduced for a thermoelectric module having an element occupying area ratio of 40% or less, by using a metalized substrate characterized in that the area of an effective element array region defined by the outer periphery of a metal electrode is 75% or less in comparison with the area of the metalized substrate.

The stress is reduced for a thermoelectric module having an element occupying area ratio of 40% or less, by using a metalized substrate characterized in that the thicknesses of metalized layers and metal electrodes formed on the both sides of an insulator are 10% or less relative to the thickness of an insulating substrate.

The stress is reduced for a thermoelectric module having an element occupying area ratio of 40% or less, by setting a pre-tinning solder thickness to 30 μm or less.

The stress is reduced for a thermoelectric module having an element occupying area ratio of 40% or less, by arraying P-type thermoelectric elements and N-type thermoelectric elements in series or in parallel to form a lattice pattern while arranging no thermoelectric element at the corners of the lattice pattern.

The stress is reduced for a thermoelectric module having an element occupying area ratio of 40% or less, by forming a metalized layer region on the opposite surface to the element bonding surface of the lower metalized substrate for soldering or brazing the thermoelectric module to a package or the like so as to be located only within the projection area of the upper metalized substrate opposing the lower metalized substrate.

For a thermoelectric module having an element occupying area ratio of 40% or less, the bonding of a current induction conductor is facilitated by forming a metalized layer provided for a process for bonding the current induction conductor so as to be located independently on the same surface as the effective metalized surface.

The stress is reduced by combining a plurality of measures described above according to specifications of a thermoelectric module.

### EFFECTS OF THE INVENTION

As described above, with the thermoelectric device substrate and the thermoelectric device according to the present invention, the breakage of the elements caused by thermal stress generated during assembly or during pre-tinning performed to attach a package or an object to be cooled can be reduced even in a case of a thermoelectric module in which the cross-sectional area of thermoelectric elements becomes smaller and thus the element occupying area ratio is 40% or less. This makes it possible to meet requirements for further reduction of power consumption.

### BEST MODE FOR CARRYING OUT THE INVENTION

The present invention will be described on the basis of embodiments thereof.

FIG. 2 shows an embodiment of a thermoelectric module according to the present invention. The reference numeral 4c indicates a projected profile image of a metalized layer formed on the surface of a lower insulating substrate 2b not facing an upper insulating substrate 2a.

As seen from FIG. 2, metal electrodes 3a for electrically connecting P-type thermoelectric elements 5a and N-type thermoelectric elements 5b are formed on one surface of the upper insulating substrate 2a, while a metalized layer 4a for soldering an object to be cooled is formed on the other surface.

Metal electrodes 3b for electrically connecting the P-type thermoelectric elements 5a and N-type thermoelectric elements 5b are formed on one surface of the lower insulating substrate 2b, while a metalized layer 4b for soldering a package or a heat sink is formed on the other surface.

The P-type thermoelectric elements 5a and N-type thermoelectric elements 5b are arrayed in a lattice pattern on the metal electrodes 3a, 3b of these metalized substrates, and bonded by soldering to electrically connect them in series, whereby a thermoelectric module 1 is formed.

Usually, thermoelectric elements are arrayed in a rectangular lattice pattern. In this case, thermal stress is liable to be concentrated on the thermoelectric elements at the four corners of the rectangle. Therefore, the concentration of stress is alleviated by placing no thermoelectric element at the four corners of the array.

The metalized layers 4a, 4b on the metalized substrates according to the present invention are preferably divided into a plurality of regions. This makes it possible to reduce the warpage (deflection in the thickness direction) of the substrates caused by a difference in thermal expansion coefficient between the insulating substrates and the metalized layers.

It is also preferable to arrange the thermoelectric elements as centrally as possible on the metalized substrates. This makes it possible to bond the thermoelectric elements in a region of the substrate where the defection in the thickness direction is small, and thus to reduce the thermal stress applied to the thermoelectric elements.

As shown in FIG. 2, the lower insulating substrate 2b is further provided with current terminals 6 for joining current induction conductors 7 such as lead wires or posts, and thus the longitudinal or transverse dimension of the lower insulating substrate 2b may be greater than that of the upper insulating substrate.

In such a case, it is desirable not to form the lower metalized layer in the region outside the projected image area of the upper insulating substrate 2a as shown in FIG. 2.

This makes it possible to reduce the warpage of the part outside the projected image area of the upper insulating substrate 2a, and hence to reduce the stress applied to the thermoelectric elements due to the warpage.

However, when taking this measure, the thermoelectric module may become unstable during the process to join the current induction conductors 7 such as lead wires or posts, possibly resulting in trouble of workability.

In such a case, it is preferable to independently arrange supporting metalized layers 4d serving as a supporter, as shown in FIG. 5, in a rear side region corresponding to the regions where the current induction conductors 7 are to be bonded. The supporting metalized layers 4d desirably have a thickness close to that of the lower metalized layers 4b, and may be formed simultaneously with the lower metalized layers 4b. The supporting metalized layers 4d need not necessarily be located within the projected image area below the current induction conductors 7, and may be formed in any size and shape as long as stable support is ensured.

The thickness of the metalized layers 4a and 4b on the metalized substrates are desirably formed as small as possible. This makes it possible to reduce the warpage of the metalized substrates caused by a difference in thermal expansion coefficient between the insulating substrates 2 and the metalized layers 4.

This makes it possible to reduce the warpage of the substrates caused by difference in thermal expansion between the insulating substrates 2 and the metalized layers 4 during soldering of the thermoelectric elements or during the pre-tinning process, and thus to reduce the stress applied to the P-type thermoelectric elements 5a and N-type thermoelectric elements 5b.

### EXAMPLES

A manufacturing method of the thermoelectric module according to the present invention will be described.

Alumina was used as an insulating substrate and a metalized layer comprising three layers of Cu/Ni/Au was formed thereon in a desired shape by plating, thermal spraying or the like.

Bi—Te thermoelectric elements were then bonded to the surfaces of metal electrodes on the metalized substrate with the use of AuSn solder which was heated to a temperature equal to or higher than the melting point (280° C.) of the solder, whereby a thermoelectric module was manufactured.

A visual test was conducted on the thermoelectric modules thus obtained with the use of a microscope with a magnification of 200× to examine the thermoelectric elements. The number of thermoelectric modules in which cracks were observed in the thermoelectric elements was counted to calculate the rate of defectives with cracked elements represented by the expression [the number of thermoelectric modules in which thermoelectric elements are cracked/the total number of thermoelectric modules introduced into the process].

Further, Sn—Ag—Cu solder was pre-tinned on the metalized layer 4b of the thermoelectric module. The heating temperature during this pre-tinning was set to 240° C., slightly higher than the melting point of the Sn—Ag—Cu solder (217° C.).

A visual test was conducted on the pre-tinned thermoelectric modules with the use of a microscope with a magnification of 200× to examine the thermoelectric elements. The number of thermoelectric modules in which cracks were observed in the thermoelectric elements was counted to calculate the rate of defectives with cracked elements as described above.

Table 1 below shows the rate of the defectives with cracked elements obtained during the assembly and the rate of the defectives with cracked elements during the pre-tinning in a case of the thermoelectric modules of the examples of the present invention and a case of conventional thermoelectric modules.

As shown in FIG. 3, the region on the insulating substrate 2 defined by the outer periphery of the metal electrodes 3 for electrically connecting the thermoelectric elements 5a and 5b, that is, the region surrounded by the long dashed double-short dashed line in FIG. 3 is defined as the effective element array, and the area of this region is defined as the effective element array area. The region defined by the outer periphery of the metalized layer on the rear surface of the same insulating substrate as shown in FIG. 4, that is, the region surrounded by the long dashed double-short dashed line in FIG. 4 is defined as the effective metalized region 9, and the area of this region is defined as the effective metalized region area.

In Example 1 of the present invention, in addition to the conditions described in Table 1, the lower metalized substrate is provided with the metalized layer 4b and the supporting metalized layer 4d, and no thermoelectric elements are arranged at the four corners of the array.

Example 2 of the present invention is different from Comparative Example 3 in that slits are formed in the metalized layers 4a and 4b.

In Examples 1 and 2 of the present invention, favorable test results were obtained with the rate of defectives being 20% or less.

In Comparative Examples 1 to 4, in contrast, the rate of defectives was 50% or higher. During pre-tinning, in particular, the rate of cracked defectives was 100% in some of Comparative Examples, and the results were obviously inferior to those of Examples of the present invention.

TABLE 1

| | | | Effective element | Effective element | Effective metalized | Effective metalized |
|---|---|---|---|---|---|---|
| | | | array area/ | array area/ | region area/Effective | region area/Effective |
| | Element | | Substrate area | Substrate area | element array area | element array area |
| | occupancy | | Substrate 1 | Substrate 2 | Substrate 1 | Substrate 2 |
| | % | Slit | (Note) | (Note) | (Note) | (Note) |
| Example 1 | 18.8 | Quartering | 0.50 | 0.39 | 1.23 | 1.23 |
| | | slits | | | | |
| Example 2 | 18.8 | Quartering | 0.74 | 0.58 | 1.17 | 1.52 |
| | | slits | | | | |
| Comparative | 20.3 | Nil | 0.83 | 0.63 | 1.06 | 1.41 |
| Example 1 | | | | | | |
| Comparative | 20.3 | Nil | 0.83 | 0.63 | 1.06 | 1.41 |
| Example 2 | | | | | | |
| Comparative | 18.8 | Nil | 0.74 | 0.58 | 1.17 | 1.52 |
| Example 3 | | | | | | |
| Comparative | 18.8 | Nil | 0.74 | 0.58 | 1.17 | 1.52 |
| Example 4 | | | | | | |

| | | Substrate 1 | Substrate 2 | | |
|---|---|---|---|---|---|
| | | (Note) | (Note) | Rate of cracked | Rate of cracked |
| | Metalized layer | pre-tinned | pre-tinned | defectives during | defectives during |
| | thickness/Insulating | solder thickness | solder thickness | assembly | pre-tinned soldering |
| | substrate thickness | μm | μm | % | % |
| Example 1 | 5.50 | 0 | 30 | 0 | 0 |
| Example 2 | 8.50 | 30 | 30 | 0 | 11 |
| Comparative | 11.50 | 0 | 30 | 50 | 86 |
| Example 1 | | | | | |
| Comparative | 11.50 | 0 | 60 | 50 | 100 |
| Example 2 | | | | | |
| Comparative | 8.50 | 0 | 30 | 0 | 80 |
| Example 3 | | | | | |
| Comparative | 8.50 | 0 | 60 | 0 | 100 |
| Example 4 | | | | | |

(Note)
Substrate 1: Upper metalized substrate
Substrate 2: Lower metalized substrate

### INDUSTRIAL APPLICABILITY

The present invention is applicable for temperature control of downsized and power-saving semiconductor laser devices for telecommunication which are expected to be even more prevalent in the future.

### BRIEF DESCRIPTION OF THE DRAWINGS

FIG. 1 shows a typical thermoelectric module structure for explaining a technical background of the present invention;

FIG. 2 is a perspective view showing a thermoelectric module according to an embodiment of the present invention;

FIG. 3 is a diagram showing an effective element array area for describing the embodiment of the present invention;

FIG. 4 is a diagram showing an effective metalized region area for describing the embodiment of the present invention; and

FIG. 5 is a plan view showing a supporting metalized layer for use in a process for bonding an insulating substrate to a current induction conductor for explaining the embodiment of the present invention.

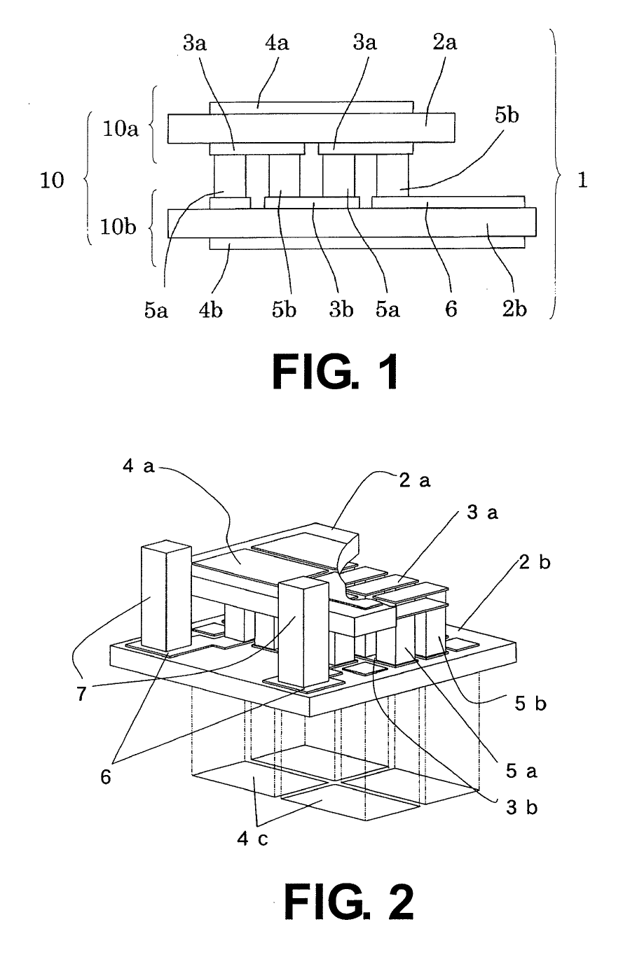

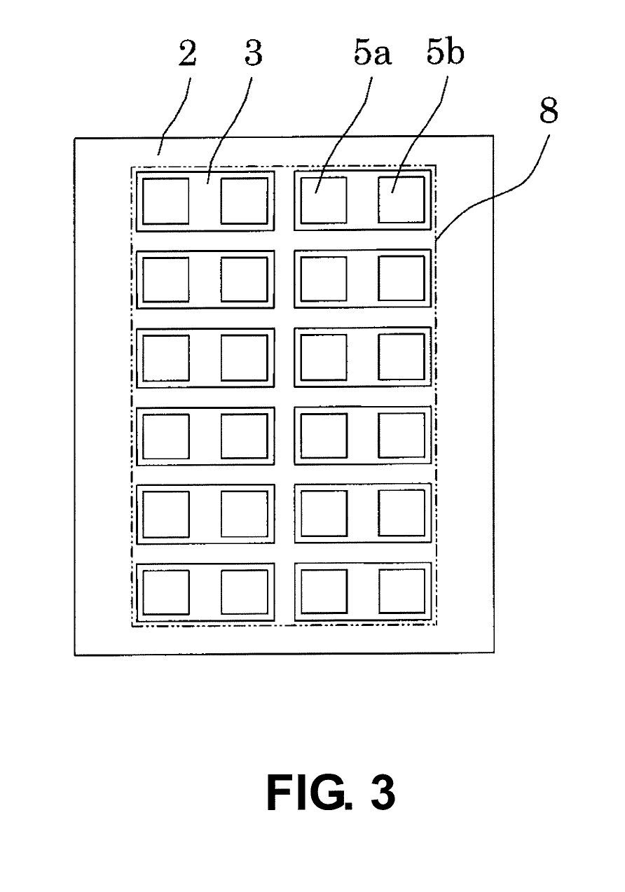

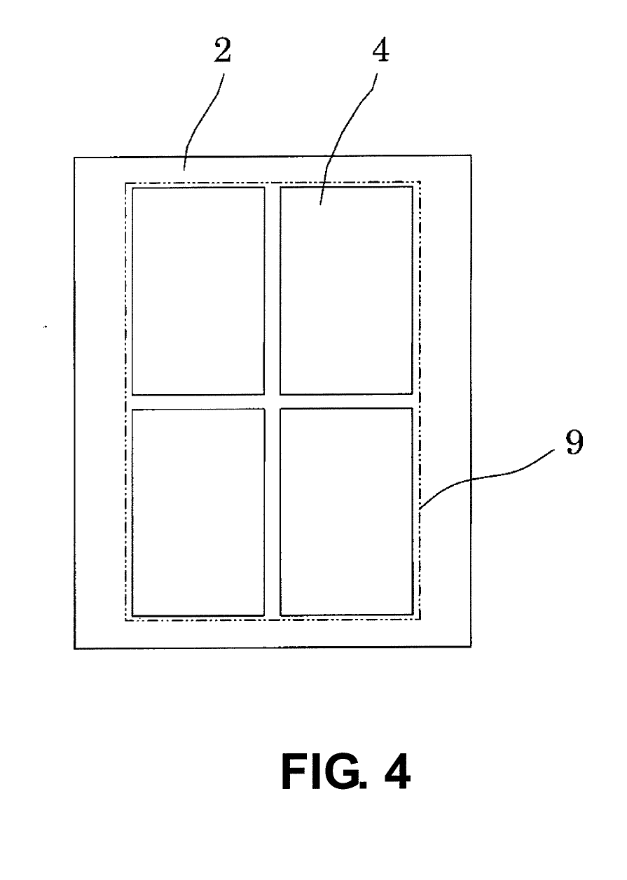

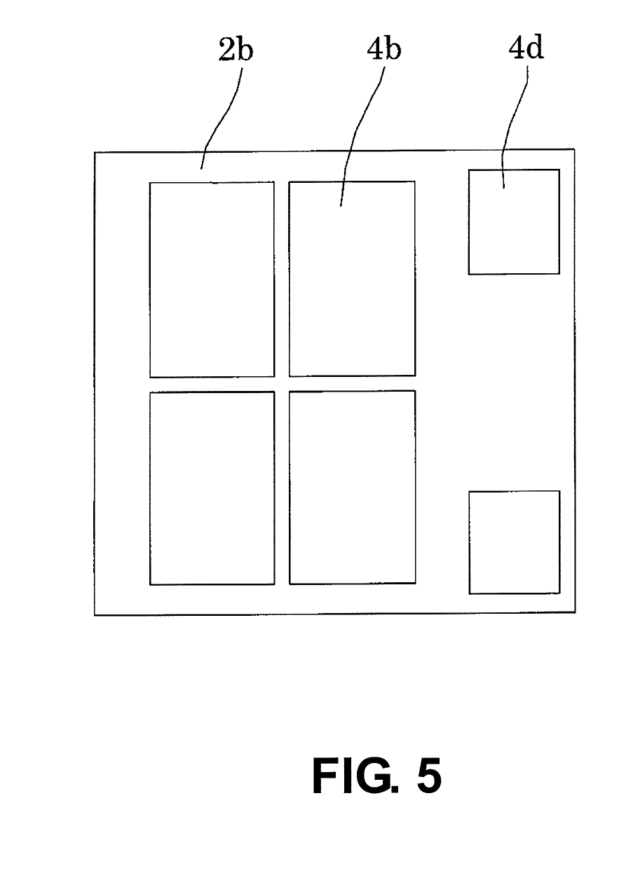

### LIST OF REFERENCE NUMERALS

1 Thermoelectric module
2 Insulating substrate
2a (Upper) insulating substrate
2b (Lower) insulating substrate
3 (Upper) metal electrode
3a (Upper) metal electrode
3b (Lower) metal electrode
4 Metalized layer
4a (Upper) metalized layer
4b (Lower) metalized layer
4c Projected profile image of (lower) metalized layer
4d Supporting metalized layer
5 Thermoelectric element
5a P-type thermoelectric element
5b N-type thermoelectric element
6 Current terminal
7 Current induction conductor
8 Effective element array
9 Effective metalized region
10 Metalized substrate
10a (Upper) metalized substrate
10b (Lower) metalized substrate

1. A metalized substrate and a thermoelectric module utilizing a Peltier effect, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and the metalized layer of the substrate is formed with a slit.

2. A thermoelectric module utilizing a Peltier effect and having a metalized substrate, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and a proportion of an area of an effective metalized region relative to an area of an effective element array region is 130% or less.

3. A thermoelectric module utilizing a Peltier effect and having a substrate, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and an area of an effective element array region is 75% or less in comparison with the area of the insulating substrate.

4. A metalized substrate and a thermoelectric module utilizing a Peltier effect, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and thicknesses of metalized layers and metal electrodes each formed on either side of the insulating substrate are 10% or less of a thickness of the insulating substrate.

5. A thermoelectric module utilizing a Peltier effect, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and a thickness of pre-tinned solder is 30 μm or less.

6. A thermoelectric module utilizing a Peltier effect, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and the thermoelectric module has an element array in which P-type and N-type thermoelectric elements are arrayed in series or in parallel to form a lattice pattern while no element is placed at corners of the lattice pattern.

7. A thermoelectric module utilizing a Peltier effect, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and an effective metalized region of a lower metalized substrate for soldering or brazing the module to a package or the like is located only within a projection area of an upper metalized substrate opposing the lower metalized substrate.

8. A thermoelectric module utilizing a Peltier effect and having a metalized substrate, wherein
an element occupying area ratio defined by a proportion of a total sum of cross-sectional areas, perpendicular to a current flowing direction, of thermoelectric elements relative to an area of an insulating substrate being in contact with an object to be cooled via a metalized layer is 40% or less, and a supporting metalized layer provided for a process for bonding a current induction conductor is present independently on the same surface as an effective metalized surface.
